(19) United States
(12) Patent Application Publication
(10) Pub. No.: US 2021/0054505 A1
(43) Pub. Date: Feb. 25, 2021

(54) CRACKING DEVICE AND DEPOSITION APPARATUS INCLUDING THE SAME

(71) Applicant: ELECTRONICS AND TELECOMMUNICATIONS RESEARCH INSTITUTE, Daejeon (KR)

(72) Inventors: Sun Jin YUN, Daejeon (KR); JungWook LIM, Daejeon (KR)

(73) Assignee: ELECTRONICS AND TELECOMMUNICATIONS RESEARCH INSTITUTE, Daejeon (KR)

(21) Appl. No.: 16/934,129

(22) Filed: Jul. 21, 2020

(30) Foreign Application Priority Data
Aug. 22, 2019 (KR) 10-2019-0103331
Apr. 13, 2020 (KR) 10-2020-0044801

(51) Int. Cl. C23C 16/448

(52) U.S. Cl. CPC C23C 16/4488

(57) ABSTRACT

The present disclosure relates to a cracking device and a deposition apparatus including the same, and more particularly includes a source supply part for supplying a source gas, a cracking part for decomposing the source gas supplied from the source supply part, a distribution part disposed between the source supply part and the cracking part and distributing the source gas to the cracking part; and a heating element for heating the cracking part. The cracking part extends in a first direction, the cracking part has a first width in a second direction crossing the first direction, the cracking part has a first height in a third direction perpendicular to the first and second directions, and the ratio of the first width to the first height is about 2-20.

### CROSS-REFERENCE TO RELATED APPLICATIONS

This U.S. non-provisional patent application claims priority under 35 U.S.C. § 119 of Korean Patent Applications No. 10-2019-0103331, filed on Aug. 22, 2019, and No. 10-2020-0044801, filed on Apr. 13, 2020, the entire contents of which are hereby incorporated by reference.

### BACKGROUND

The present disclosure relates to a cracking device and a deposition apparatus including the same.

The metal chalcogenide compounds are materials widely used for semiconductor elements, photoelectric devices, photovoltaic devices, and the like. A chemical vapor deposition (CVD) method, a metalorganic CVD (MOCVD) method, and the like have been used as methods for preparing metal chalcogenide compounds. The CVD method is a method in which a metal precursor and a chalcogen precursor react with each other in a gas phase to synthesize a metal chalcogenide, and the formed metal chalcogenide is deposited on a substrate. The MOCVD is a case in which the metal precursor is an organometallic compound. In another example, in case of a CuInGaSe (CIGS) solar cell, a physical vapor deposition (PVD) method such as a sputter deposition method or an electron beam deposition method is used to manufacture a metal chalcogenide compound by sputtering or vaporizing the component materials.

In order to use the metal chalcogenide for a semiconductor element such as a transistor, a technique for forming a high-quality metal chalcogenide film having excellent crystallinity is required. In particular, in order to obtain a two-dimensional thin film in which monolayers are stacked layer by layer, it is well known that a elaboratively (or delicately) adjusted process and a high growth temperature are required. A CVD process for forming metal chalcogenides also requires a high temperature of about 700° C. or higher.

### SUMMARY

The present disclosure provides a cracking device capable of uniformly forming a large-area film on a substrate.

The present disclosure also provides a deposition apparatus including the cracking device.

An embodiment of the inventive concept provides a cracking device including a source supply part configured to supply a source gas or a source vapor; a cracking part configured to pyrolyze the source gas or a source vapor supplied from the source gas supply part; a distribution part disposed between the source supply part and the cracking part and configured to distribute the source gas to the cracking part; and a heating element (heating coil or heating plate) configured to heat the cracking part. A coil shape, a plate shape, or the like may be used for the detailed shape of the heating element, and does not affect the effect of the inventive concept. The cracking part extends in a first direction, the cracking part has a first width in a second direction crossing the first direction, the cracking part has a first height in a third direction perpendicular to the first and second directions, and the ratio of the first width to the first height may be about 2-20. More specifically, a ratio of the first width to the first height may be about 5-10.

In an embodiment of the inventive concept, a deposition apparatus may include a chamber having a susceptor for placing a substrate and a cracking device connected to the chamber. The cracking device may include: a source supply part for supplying a source gas or a source vapor; a cracking part for pyrolyzing the source gas or a source vapor supplied from the source supply part; and a heating part for heating the cracking part. The cracking part extends in the first direction, the cracking part may have a first width in the second direction crossing the first direction, the substrate may have a second width in the second direction, and the second width may be greater than the second width. The second width may be about 1-10 times the first width.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a cross-sectional view for describing a deposition apparatus according to embodiments of the inventive concept;

FIG. 2 is a perspective view schematically illustrating a cracking device (CAP) of a deposition apparatus of FIG. 1;

FIG. 3 is a cross-sectional view taken along line I-I′ of FIGS. 1 and 2;

FIG. 4 is an expanded cross-sectional view of region M of FIG. 3;

FIGS. 5A to 5D are perspective views schematically illustrating a deposition process according to embodiments of the inventive concept;

FIG. 6 is a perspective view schematically illustrating a cracking (CAP) device according to another embodiment of the inventive concept;

FIGS. 7A and 7B are cross-sectional views taken along respective lines I-I′ and II-II′ of FIG. 6;

FIG. 8 is an expanded cross-sectional view of region N of FIG. 7A; and

FIGS. 9 and 10 are cross-sectional views for describing respective cracking devices according to other embodiments and taken along line I-I′ of FIG. 6.

### DETAILED DESCRIPTION

In order to sufficiently understand the configurations and effects of the embodiments of the inventive concept, preferable embodiments of the inventive concept will be described. However, the inventive concept may be embodied in different forms and should not be construed as limited to the embodiments set forth herein. Rather, these embodiments are provided so that this disclosure will be thorough and complete, and will fully convey the scope of the present invention to those skilled in the art.

In this specification, when it is described that an element is on another component, this means the element may be directly provided on another element or a third element may also be interposed therebetween. Also, in the figures, the thicknesses of elements are exaggerated for effective illustration of technological contents. Throughout the specification, portions referred to by like reference numerals refer to like elements.

In various embodiments of the specification, the terms such as “first”, “second” or “third” are used to describe various elements, but these elements should not be limited by these terms. These terms are merely used to discriminate one element from other elements. Embodiments illustrated and described herein include complementary embodiments thereof.

The terms used in this specification are used for description of exemplar embodiments, and are not for limiting the exemplary embodiments of the inventive concept. In the specification, singular terms include plural terms unless mentioned otherwise in the statement. The terms “comprises” and/or “comprising” used in the specification do not exclude the presence or addition of one or more components other than the aforementioned components.

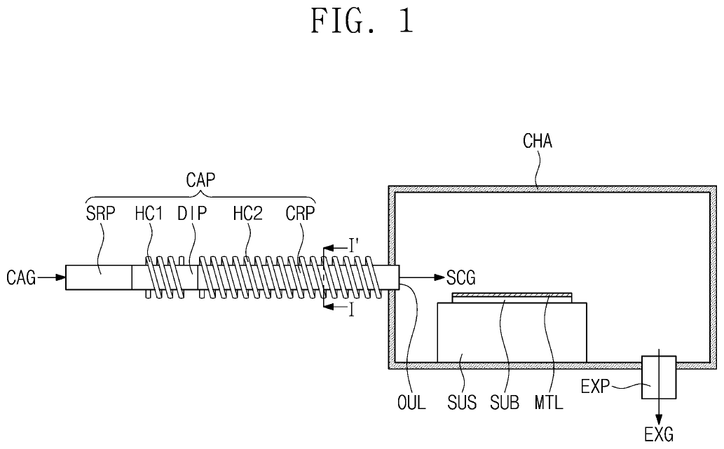

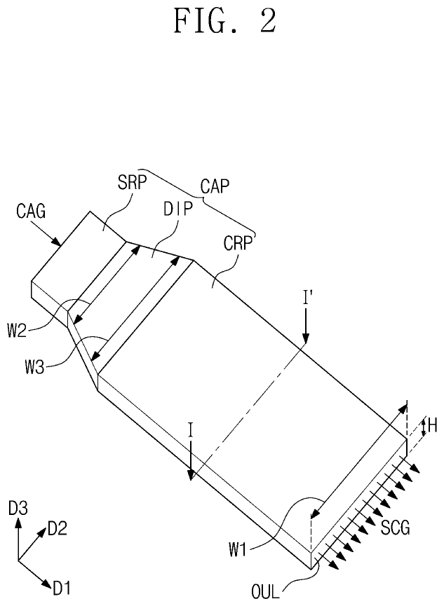

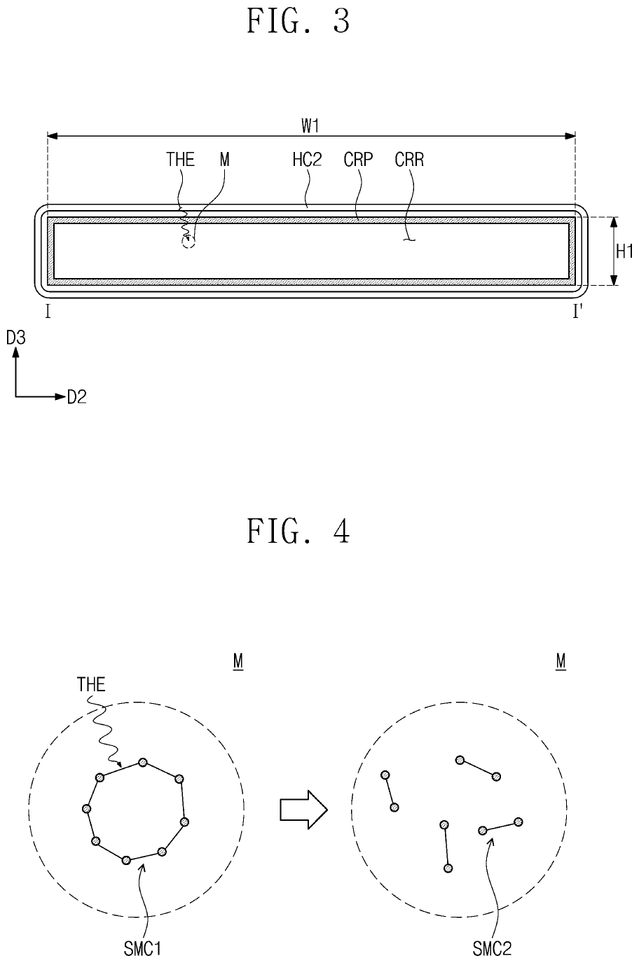

FIG. 1 is a cross-sectional view for describing a deposition apparatus according to embodiments of the inventive concept. FIG. 2 is a perspective view schematically illustrating a cracking device (CAP) of a deposition apparatus of FIG. 1. FIG. 3 is a cross-sectional view taken along line I-I′ of FIGS. 1 and 2. FIG. 4 is an expanded cross-sectional view of region M of FIG. 3.

Referring to FIGS. 1 to 4, a deposition apparatus according to embodiments of the inventive concept may include a cracking device (CAP) and a chamber (CHA). For example, the deposition apparatus illustrated in FIG. 1 may be a traveling flow reactor. This reactor uses a method in which reaction source steam or a source gas flows into one side of a substrate SUB and flow out to an opposite side.

The cracking device CAP may include a source supply part SRP, a cracking part CRP, and a distribution part DIP between the source supply part SRP and the cracking part CRP.

The source supply part SRP may supply a source material to be used in a deposition process to a distribution part DIP. For example, the source supply part SRP may include a source reservoir in which a source material is stored and a heater for heating the source reservoir. The source reservoir is heated, so that the source material inside the source reservoir may be vaporized. The source material may be stored in the source reservoir in a solid or liquid state. For example, the source material may include a chalcogen material such as sulfur (S) or selenium (Se).

The source materials usable in the embodiments of the inventive concept are not limited to the above-mentioned chalcogen materials. For example, the source materials may also include a pnictogen such as arsenic (As) or silicon precursor material. That is, a source material required to be pyrolyzed into highly reactive small molecules may be used for the cracking device CAP in the embodiment of the inventive concept.

A carrier gas CAG may be supplied to the source supply part SRP. The carrier gas CAG may flow in a first direction D1. The carrier gas CAG may carry the vaporized source material in a first direction D1. The carrier gas CAG may include an inert gas such as helium, neon, argon, krypton, or nitrogen.

The vaporized source material carried by a source gas SCG may flow to the cracking part CRP via the distribution part DIP. The distribution part DIP may uniformly distribute the source gas SCG carrying the source vapor to the cracking part CRP. The width of the distribution part DIP may be constant in a second direction D2. Alternatively, the width of the distribution part DIP in the second direction may increase toward the first direction D1. The temperature of the distribution part DIP may be higher than the temperature of the source supply part SRP. For example, the distribution part DIP may have a second width W2 adjacent to the source supply part SRP, and have a third width W3 adjacent to the cracking part CRP. The third width W3 may be greater than the second width W2. A first heating element HC1 may surround the distribution part DIP. The first heating element HC1 may heat the inside of the distribution part DIP.

The cracking part CRP may extend in the first direction D1. A gas flow passage CRR in which the source gas SCG flows may be defined inside the cracking part CRP. The source gas SCG may flow in the first direction D1 through the gas flow passage CRR.

The cracking part CRP may have a first width W1 in the second direction D2. The first width W1 may be greater than the third width W3. The cracking part CRP may have a first height H1 in the vertical direction, that is, in the third direction D3. The ratio (that is, W1/H1) of the first width W1 to the first height H1 may be about 2 to about 20. More specifically, the ratio of the first width W1 to the first height H1 may be about 5 to about 10. In other words, the cracking part CRP may have a plate shape having a longitudinal axis in the second direction D2. The cracking part CRP may have a hexahedral shape having the width greater than the height thereof. The shape of the cracking part CRP may have a different shape from a hexahedron under a condition in which the ratio W1/H1 in the embodiment of the inventive concept is maintained.

A second heating element HC2 may surround the cracking part CRP. The second heating element HC2 may heat the gas flow passage CRR of the cracking part CRP. The cracking part CRP may include any one or more metal elements or an alloy selected from the group consisting of Pt, W, Ta, Ir, Re and Nb so as to endure heating from the second heating element HC2.

As illustrated in FIG. 1, each of the first heating element HC1 and the second heating element HC2 may include a heating coil. In another embodiment of the inventive concept, the first heating element HC1 and the second heating element HC2 may have a plate-like shape aside from a coil shape. In other words, each of the first heating element HC1 and the second heating element HC2 may include a heating plate. In the embodiment of the inventive concept, each of the heating elements may include means capable of heating.

Referring to FIG. 4, the source gas SCG injected into the cracking part CRP may include first source molecules SMC1. The first source molecules SMC1 may be relatively large molecules. For example, when the source gas SCG is sulfur, the first source molecules SMC1 may be ring type S₈. Due to heat energy THE transferred from the second heating element HC2, the first source molecules SMC1 may be pyrolyzed into relatively small source molecules SMC2. For example, the second source molecules SMC2 may be any one selected from S₂, S₃ and S₄ or a gas mixture thereof. In general, smaller molecules may be formed at higher temperatures.

For example, when the source gas SCG is selenium, the first source molecules SMC1 may be ring-type Se₈. Due to heat energy THE transferred from the second heating element HC2, the first source molecules SMC1 may be pyrolyzed into relatively small source molecules SMC2. For example, the second source molecules SMC2 may be any one selected from Se₂, Se₃ and Se₄ or a gas mixture thereof.

The cracking part CRP may have an outlet port OUL at an end thereof. The outlet port OUL may have a relatively large first width W1 in the second direction D2. The source gas SCG pyrolyzed into second source molecules SMC2 may be supplied to the chamber CHA through the outlet port OUL. A liner for blocking direct contact between the inner surface of the cracking part and the source gas SCG inside the cracking part CRP may be disposed. Quartz which is chemically stable and can endure a high temperature may be used for the material of the liner. The shape of the liner may be the same as the shape of the inside of the cracking part CRP. Alternatively, the shape of the liner may be composed of a plurality of cylindrical tubes.

The outlet port OUL of the cracking part CRP may be connected to the inside of the chamber CHA. The source gas SCG effused from the cracking part CRP may be supplied into the chamber CHA. Since the pressure of the cracking part CRP is higher than the pressure of the chamber, the source gas SCG may radially effused from the outlet port OUL and supplied into the chamber CHA. The speed at which the source gas SCG is supplied may be dependent on the flow rate of a carrier gas. A susceptor SUS and a substrate SUB loaded on the susceptor SUS may be provided inside the chamber CHA. The susceptor SUS may heat the substrate SUB. A resistance heating method and a lamp-type heating method may be used for the susceptor. A precursor film, for example, a metal precursor film MTL may be formed on the substrate SUB.

For example, the chamber CHA may have a cylindrical tube shape. In another example, the chamber CHA may have a rectangular box shape. The chamber CHA is shielded, and may prevent infiltration of external gases or air. The chamber CHA may include quartz having high mechanical strength and chemical durability. The chamber CHA may include stainless steel having high mechanical strength and chemical durability. In another embodiment of the inventive concept, a separate liner for preventing direct contact between a metallic chamber wall and the gas may be disposed. The liner may include quartz.

The source gas SCG supplied into the chamber CHA may be provided on to the substrate SUB. The source gas SCG may flow in the first direction on the metal precursor film MTL. The source gas SCG may react with a precursor film formed on the substrate SUB and generate a product. Reaction residues and the source gas SCG that have passed through the metal precursor film MTL may be evacuated to the outside as an exhaust gas EXG through an outlet part EXP of the chamber CHA. The outlet part EXP may adjust the flow of the source gas SCG inside the chamber CHA and allow the source gas SCG to flow in the first direction on the metal precursor film MTL.

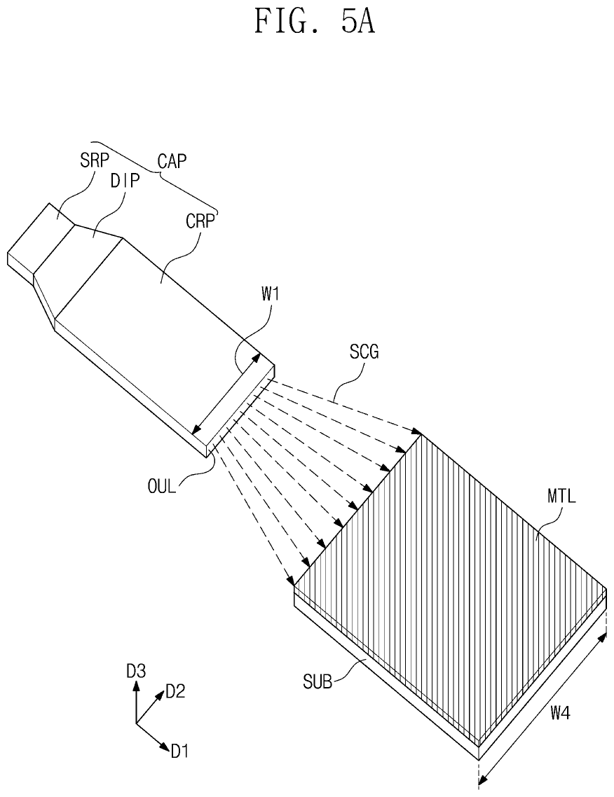

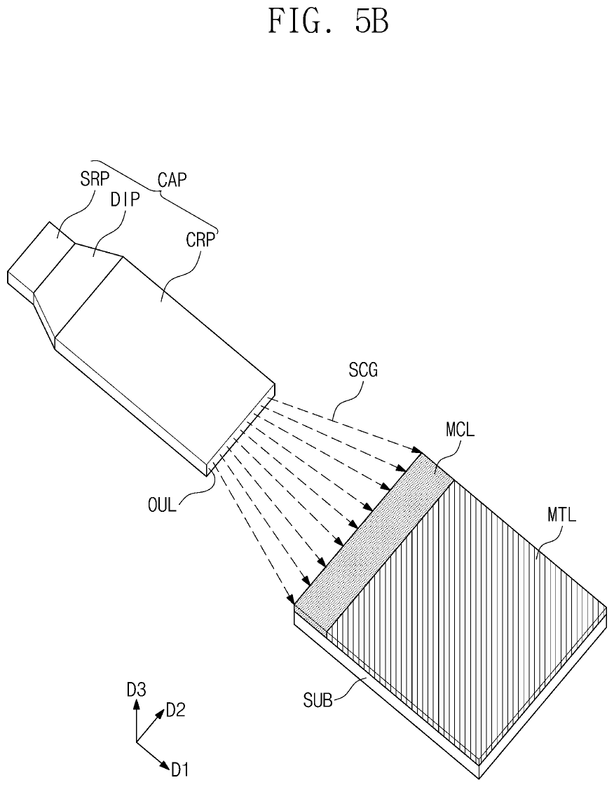

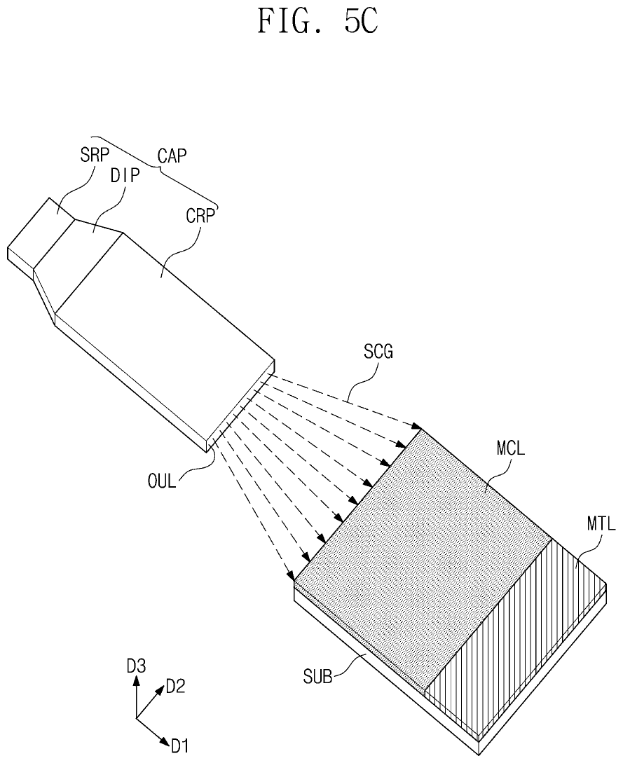

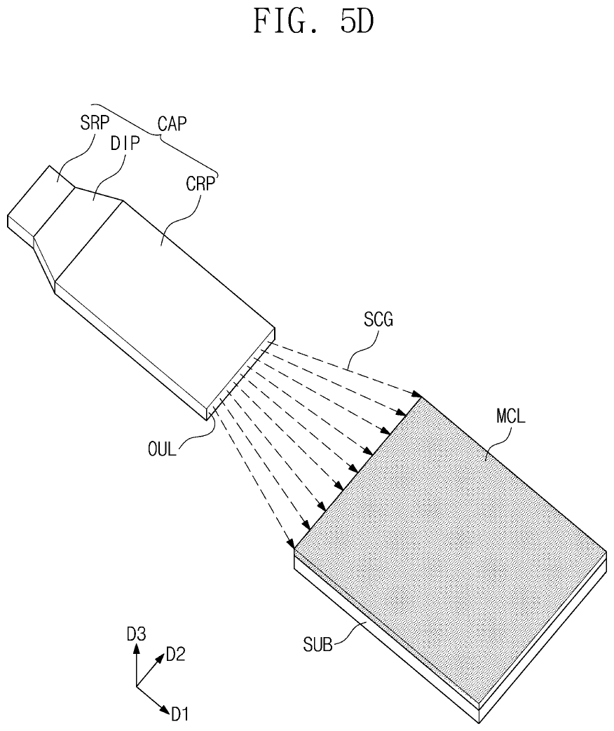

FIGS. 5A to 5D are perspective views schematically illustrating a deposition process according to embodiments of the inventive concept.

Referring to FIGS. 1 and 5A, a substrate SUB inside a chamber CHA may be positioned at an outlet port OUL of a cracking part CRP in the first direction D1. The substrate SUB may have a fourth width W4 in the second direction D2. The fourth width W4 may be greater than a first width W1 of the outlet port OUL of the cracking part CRP. For example, the fourth width W4 may be about 1-20 times the first width W1. More specifically, the fourth width W4 may be about 1-10 times the first width W1.

A metal precursor film MTL may be provided on the substrate SUB. The metal precursor film MTL may be a metal film such as tungsten (W), molybdenum (Mo), titanium (Ti), zinc (Zn), vanadium (V), nickel (Ni), manganese (Mn), iron (Fe), hafnium (Hf), copper (Cu), bismuth (Bi), rhenium (Re), antimony (Sb), strontium (Sr), indium (In), or zirconium (Zr). The metal precursor film MTL may be formed on the entire or a portion of the surface of the substrate SUB. The metal precursor film MTL may have a thickness of about 0.2-100 nm. More specifically, the metal precursor film MTL may have a thickness of about 0.2-20 nm. The metal precursor film MTL may be a compound thin film including a metal. The compound thin film may be an oxide film of the metal. The oxide film collectively refers to a stoichiometric film or a film partially including oxygen.

A source gas SCG may be supplied to a distribution part DIP through a source supply part SRP. A first heating element HC1 may heat the inside of the distribution part DIP. The temperature inside the distribution part DIP in which the source gas flows may be about 100-600° C. The temperature inside the distribution part may be higher than the source supply part and lower than the temperature of the cracking part.

The source gas SCG may be supplied to the cracking part CRP through the distribution part DIP. A second heating element HC2 may heat a gas flow passage CRR of the cracking part CRP. The temperature of the gas flow passage CRR in which the source gas flows may be about 700-1,100° C. More specifically, the temperature of the gas flow passage may be about 800-1,000° C. As described above with reference to FIG. 4, the source gas SCG may be pyrolyzed from first source molecules SMC1 into second molecules SMC2 under high temperatures. The source gas SCG effused from the outlet port OUL of the cracking part CRP may flow on a metal precursor film MTL in the first direction D1.

Referring to FIG. 5B, the source gas SCG and the metal precursor film MTL react with each other and a metal chalcogenide film MCL may be formed. Specifically, the metal of the metal precursor film MTL and the source gas SCG react with each other and a metal chalcogenide may be formed. One region of the metal precursor film MTL adjacent to the outlet port OUL may firstly converted into a metal chalcogenide film MCL. As described above with reference to FIG. 4, a chalcogen gas such as sulfur or selenium passes through the cracking part CRP, so that small-size molecules (that is, second source molecules SMC2) may be formed. The reactivity between the chalcogen gas and the metal precursor film MTL may be improved due to the small-size molecules.

Referring to FIGS. 5C to 5D, the metal chalcogenide film MCL may gradually expand in the first direction in which the source gas SCG flows. Conversely, the metal precursor film MTL may be contracted in the first direction D1. Consequently, the metal precursor film MTL may completely be converted into the metal chalcogenide film MCL.

The state, in which the metal chalcogenide film MCL gradually expands, may not clearly appear as illustrated in FIGS. 5B to 5D. In other words, unlike illustrated in FIGS. 5B to 5D, the boundary between the metal chalcogenide film MCL and the metal precursor film MTL may not be clearly distinguished. For example, the surface of the metal precursor film MTL is chalcogenized, and then, chalcogenization may proceed in the depth direction of the metal precursor film MTL. That is, the expanding state of the metal chalcogenide film MCL illustrated in FIGS. 5B to 5D is merely illustrated to help understand the inventive concept, and the embodiment of the inventive concept is not limited to the expanding state illustrated in FIGS. 5B to 5D.

When the reaction between the metal precursor in one region of the metal precursor film MTL and the source gas SCG is completed, the metal in the one region does not react with the source gas SCG any more. Thus, the source gas SCG may sequentially react with the metal in another region adjacent to the one region in the first direction D1. Consequently, the metal chalcogenide film MCL may be formed in a self-saturation manner. A self saturation-type reaction may proceed in the first direction D1 along the surface of the metal precursor film MTL. In addition, the self saturation-type reaction may proceed in the depth direction from the surface of the metal precursor film MTL.

Cracking devices according to related arts each have a cylindrical tube shape, and in this case, an outlet port of a cracker has a relatively small diameter. Thus, a typical cracker has a problem in that a source gas may not easily be supplied uniformly on to a large-area substrate. In addition, among related arts, there is an example in which the size of the outlet port is formed to be smaller than the cross-sectional area of a cracking part, but such a structure exhibits remarkably different effects from the inventive concept because small molecules formed by cracking are aggregated again and enlarged.

In a cracking device CAP according to embodiments of the inventive concept, the cracking part CRP and the outlet port thereof may have a relatively large width W1. The source gas SCG may uniformly be supplied to the entire surface of the substrate SUB through a large-sized outlet port OUL. Thus, the metal chalcogenide film MCL may be formed effectively and uniformly by a self-saturation method on the large-size substrate SUB having the fourth width W4.

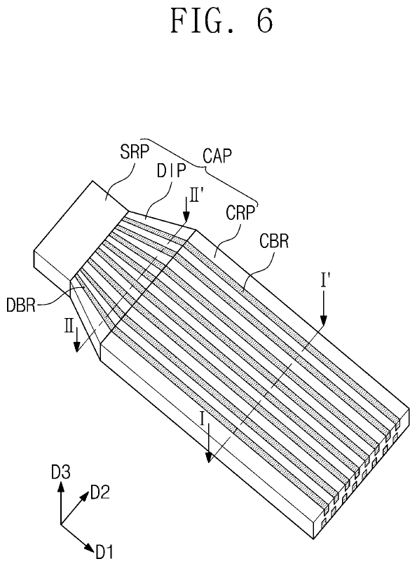

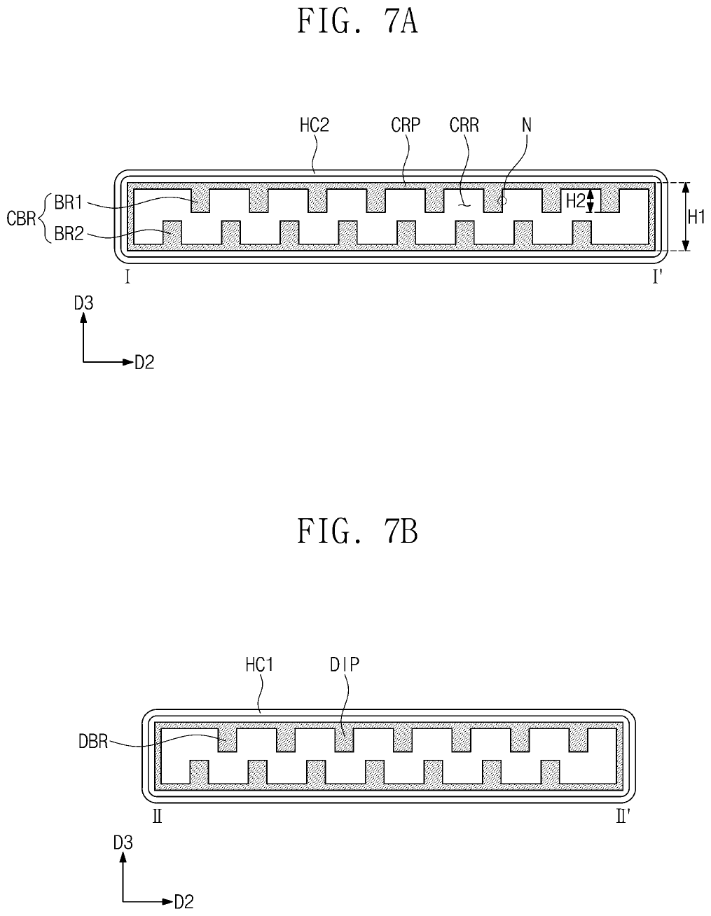

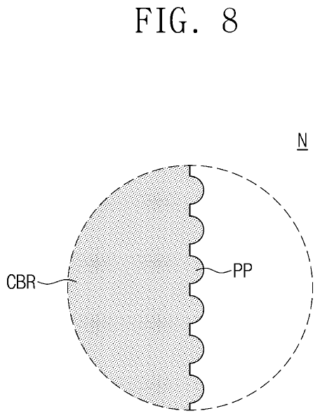

FIG. 6 is a perspective view schematically illustrating a cracking (CAP) device according to another embodiment of the inventive concept. FIGS. 7A and 7B are cross-sectional views taken along respective lines I-I′ and II-II′ of FIG. 6. FIG. 8 is an expanded cross-sectional view of region N of FIG. 7A.

Referring to FIGS. 6, 7A, 7B and 8, a cracking part CRP may include therein a plurality of cracking bars CBR. The plurality of cracking bars CBR may extend in parallel in the first direction D1.

The cracking bars CBR may include: first bars BR1 provided on an upper portion of the cracking part CRP; and second bars BR2 provided on a lower portion of the cracking part CRP. The first and second bars BR1 and BR2 may protrude toward the inside of the cracking part CRP. A gas flow passage CRR may be defined inside the cracking part by the first and second bars BR1 and BR2. The shapes of the cracking bars CBR are exemplarily illustrated and may be cylindrical shapes.

The first bars BR1 may be arranged along the second direction D2 at a constant pitch. The second bars BR2 may be arranged along the second direction D2 at the pitch. The pitch of the first bars BR1 and the pitch of the second bars BR2 may substantially be the same. The second bars BR2 may be arranged offset by a half pitch from the first bars BR1.

The cracking part CRP may have the first height H1 (?) in the third direction D3. A second height H2 may be about 0.1-0.9 times the first height H1 of the cracking part CRP.

The cracking bar CBR may increase the contact area between the cracking part CRP and the source gas SCG flowing through the gas flow passage CRR. Referring to FIG. 8, a cracking bar CBR may include protruding parts PP protruding from a surface thereof. The contact area between the cracking bar CBR and the source gas SCG may be increased through the protruding parts PP.

As the contact area between the cracking bar CBR and the source gas SCG may be increased, thermal energy may more effectively be transferred from a second heating element HC2 to the source gas SCG. In addition, since a material (quartz, metal or alloy) constituting the cracking bar CBR may function as a catalyst for decomposing source molecules, the source molecules may be pyrolyzed more effectively when the contact area between the cracking bar CBR and the source gas SCG is increased.

A distribution part DIP may include therein a plurality of distribution bars DBR similarly to the cracking part CRP. The plurality of distribution bars DBR may extend in parallel in the first direction D1. The distribution bars DBR may be connected to the respective cracking bars CBR. The distribution bars DBR may have shapes of fan ribs. The distribution bars DBR may efficiently distribute the source gas SCG supplied from the source supply part SRP and uniformly deliver to the cracking part CRP.

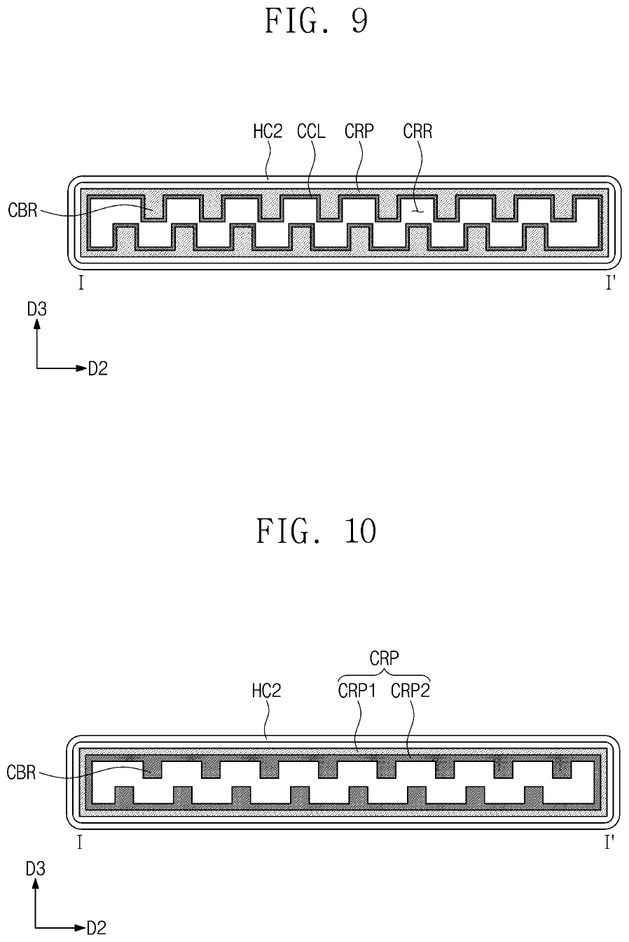

FIGS. 9 and 10 are cross-sectional views for describing respective cracking devices according to other embodiments of the inventive concept and taken along line I-I′ of FIG. 6.

Referring to FIG. 9, the inner surface of a cracking part CRP may be covered with a coating film CCL. The coating film CCL may include ceramic such as alumina, silica or metal oxide, or quartz. The coating film CCL may prevent direct contact between the inner surface of the cracking part CRP and a source gas SCG. Damage to the cracking part due to a highly reactive cracked source gas SCG may be prevented by means of the coating film CCL.

Referring to FIG. 10, a cracking part CRP may include a first cracking part CRP1 and a second cracking part CRP2 fastened to the inside of the first cracking part CRP1. The first cracking part CRP1 and the second cracking part CRP2 may include mutually different materials. The first cracking part CRP1 may include a metal or an alloy. The second cracking part CRP2 may include ceramic such as alumina, silica or metal oxide, or quartz.

The second cracking part CRP2 may be attachable to the first cracking part CRP1 and detachable from the first cracking part CRP1. Thus, when the second cracking part CRP2 is damaged due to a highly reactive cracked source gas SCG, the second cracking part CRP2 may be replaced with a new second cracking part CRP2.

The deposition apparatus according to embodiments of the inventive concept may have a cracking part and the outlet port of the cracking part may have a relatively large width. A source gas may be uniformly provided on the entire surface of the substrate through the outlet port having a large diameter or a large width. Thus, a metal chalcogenide film may effectively and uniformly be formed on a large-area substrate through a self-saturated chalcogenization reaction.

So far, embodiments of the present invention has been described with reference to the accompanying drawings, but those skilled in the art to which the present invention belongs could understand that the present invention may be implemented in other specific forms without changing the spirit or characteristics thereof. Thus, the above-disclosed embodiments are to be considered illustrative and not restrictive.

What is claimed is:

1. A cracking device comprising:
a source supply part configured to supply a source gas;
a cracking part configured to pyrolyze the source gas supplied from the source supply part;
a distribution part disposed between the source supply part and the cracking part and configured to distribute the source gas to the cracking part; and
a heating element configured to heat the cracking part, wherein:
the cracking part extends in a first direction, has a first width in a second direction crossing the first direction, and has a first height in a third direction perpendicular to the first and second directions; and
a ratio of the first width to the first height is about 2-20.

2. The cracking device of claim 1, wherein the cracking part comprises a plurality of cracking bars provided therein and extending in the first direction.

3. The cracking device of claim 2, wherein the cracking bars comprises:
first bars provided on an upper portion of the cracking part; and
second bars provided on a lower portion of the cracking part.

4. The cracking device of claim 3, wherein:
the first bars are arranged along the second direction at a pitch;
the second bars are arranged along the second direction at the pitch; and
the second bars are offset by a half of the pitch from the first bars, respectively.

5. The cracking device of claim 2, wherein:
the distribution part comprises a plurality of distribution bars provided therein and extending in a shape of fan ribs in the first direction; and
the cracking bars are connected to the respective distribution bars.

6. The cracking device of claim 1, wherein:
the cracking part comprises a coating film or a liner that is configured to cover an inner surface of the cracking part; and
the coating film or the liner comprises ceramic or quartz.

7. The cracking device of claim 1, wherein:
the cracking part comprises a first cracking part and a second cracking part fastened to an inside of the first cracking part;
the first cracking part comprising a metal; and
the second cracking part comprises ceramic or quartz.

8. The cracking device of claim 1, wherein the source gas flows in the first direction along a gas flow passage inside the cracking part.

9. The cracking device of claim 1, wherein the cracking part pyrolyzes the first source molecules of the source gas into the second source molecules smaller than the first source molecules.

10. The cracking device of claim 1, wherein:
the distribution part has a second width in the second direction adjacent to the source supply part;
the distribution part has a third width in the second direction adjacent to the cracking part;
the third width is greater than the second width; and
the first width is greater than the third width.

11. A deposition apparatus comprising:
a chamber having a susceptor for placing a substrate; and
a cracking device connected to the chamber, wherein the cracking apparatus comprises:
a source supply part configured to supply a source gas;
a cracking part configured to pyrolyze the source gas supplied from the source supply part; and
a heating element configured to heat the cracking part,
the cracking part extending in a first direction and having a first width in a second direction crossing the first direction;
the substrate having a second width in the second direction; and
the second width is about 1-10 times the first width.

12. The deposition apparatus of claim 11, wherein:
the cracking part has a first height in a third direction perpendicular to the first and second directions; and
a ratio of the first width to the first height is about 2-20.

13. The deposition apparatus of claim 11, wherein:
the chamber comprises an outlet part configured to discharge a gas; and
the outlet part allows the source gas effused from the cracking device to flow on the substrate in the first direction.

14. The deposition apparatus of claim 11, wherein the cracking part comprises a plurality of cracking bars provided therein and extending in the first direction.

15. The deposition apparatus of claim 14, wherein:
the cracking bars comprise first bars provided on an upper portion of the cracking part and second bars provided on a lower portion of the cracking part;
the first bars are arranged in the second direction at a pitch;
the second bars are arranged in the second direction at the pitch; and
the second bars are offset by a half of the pitch from the first bars, respectively.

16. The deposition apparatus of claim 11, wherein:
the cracking part comprises a coating film or a liner that is configured to cover an inner surface of the cracking part, or a liner; and
the coating film or the liner comprises ceramic.

17. The deposition apparatus of claim 11, wherein:
the cracking part comprises a first cracking part and a second cracking part fastened to an inside of the first cracking part;
the first cracking part comprises a metal; and
the second cracking part comprises ceramic or quartz.

18. The deposition apparatus of claim 11, wherein the source gas flows in the first direction along a gas flow passage inside the cracking part.

19. The deposition apparatus of claim 11, wherein the cracking part pyrolyzes a first source molecule of the source gas into a second source molecule smaller than the first source molecule.
